(19) United States
(12) Patent Application Publication
(10) Pub. No.: US 2025/0079135 A1
(43) Pub. Date: Mar. 6, 2025

(54) DEPOSITION APPARATUS AND METHOD OF OPERATING THE SAME

(71) Applicant: Samsung Display Co., Ltd., Yongin-si (KR)

(72) Inventors: Jun Hyeuk KO, Yongin-si (KR); Jong Bum KIM, Yongin-si (KR); Young Kwang LEE, Yongin-si (KR); Min Goo KANG, Yongin-si (KR); Suk Ha RYU, Yongin-si (KR); Min Chul SONG, Yongin-si (KR); Min A WOO, Yongin-si (KR)

(21) Appl. No.: 18/739,197

(22) Filed: Jun. 10, 2024

(30) Foreign Application Priority Data
Aug. 28, 2023 (KR) 10-2023-0113123

(51) Int. Cl. H01J 37/32; C23C 14/04; C23C 14/50

(52) U.S. Cl. CPC H01J 37/32669; C23C 14/042; C23C 14/50; H01J 37/32697; H01J 2237/2007; H01J 2237/332

(57) ABSTRACT

A deposition apparatus including: a base substrate; an electrostatic chuck on the base substrate; and a plate on the electrostatic chuck. The plate has a first area in which first magnet units are arranged and a second area in which second magnet units are arranged. The first magnet units are spaced apart from each other at a first distance, and the second magnet units are spaced apart from each other at a second distance. The second distance is greater than the first distance.

### CROSS-REFERENCE TO RELATED APPLICATION

The present application claims priority to and the benefit of Korean Patent Application No. 10-2023-0113123, filed on Aug. 28, 2023, in the Korean Intellectual Property Office, the entire disclosure of which is incorporated herein by reference.

### BACKGROUND

### 1. Technical

Aspects of embodiments of the present disclosure relate to a deposition apparatus and a method of operating the same.

### 2. Description of the Related Art

Recently, as interest in information displays has increased, research and development of display devices have been continuously conducted.

A display device may include layers including various materials. For example, the display device may include an anode electrode, a cathode electrode, and an organic light emitting layer disposed between the anode electrode and the cathode electrode.

The organic light emitting layer may be formed by various methods. For example, the organic light emitting layer may be formed through a deposition process using a Fine Metal Mask (FMM).

To implement (or manufacture) a high-resolution display device, structures forming the display device have been miniaturized, and accordingly, a deposition apparatus needs to be minutely operated.

The above information disclosed in this Background section is for enhancement of understanding of the background of the present disclosure, and therefore, it may contain information that does not form the prior art that is already known to a person of ordinary skill in the art.

### SUMMARY

Embodiments of the present disclosure provide a deposition apparatus that can be operated with improved reliability.

Embodiments of the present disclosure also provide a method of operating the deposition apparatus.

According to an embodiment of the present disclosure, a deposition apparatus includes: a base substrate; an electrostatic chuck on the base substrate; and a plate on the electrostatic chuck. The plate has a first area in which first magnet units are arranged and a second area in which second magnet units are arranged. The first magnet units are spaced apart from each other at a first distance, the second magnet units are spaced apart from each other at a second distance, and the second distance is greater than the first distance.

A distance between one of the first magnet units and one of the second

magnet units that is adjacent to the one of the first magnet units may be greater than the first distance.

The second magnet units may include first sub-magnet units spaced apart from each other at the second distance and second sub-magnet units spaced apart from each other at a third distance that is greater than the second distance. The first sub-magnet units may be closer to the first magnet units than the second sub-magnet units are.

A distance between one of the first magnet units and one of the second magnet units that is adjacent to the one of the first magnet units may be greater than the second distance.

A magnetic flux density of the first magnet units may be smaller than a magnetic flux density of the second magnet units.

The electrostatic chuck may have a first electrode area and a second electrode area different from the first electrode area. When viewed on a plane, the first electrode area and the first area may overlap each other.

At least one of the first magnet units and the second magnet units may include a permanent magnet.

The deposition apparatus may further include a driver configured to independently control a voltage applied to each of the first electrode area and the second electrode area.

According to another embodiment of the present disclosure, a deposition apparatus includes: a base substrate; an electrostatic chuck on the base substrate, the electrostatic chuck having a first electrode area and a second electrode area different from the first electrode area; a driver configured to independently control a voltage applied to each of the first electrode area and the second electrode area; and a plate on the electrostatic chuck. The plate has a first area in which first magnet units are arranged and a second area in which second magnet units are arranged.

According to another embodiment of the present disclosure, a method of operating a deposition apparatus includes: arranging, on a base substrate, an electrostatic chuck having a first electrode area and a second electrode area different from the first electrode area; applying a first voltage to the first electrode area and applying a second voltage lower than the first voltage to the second electrode area; and arranging a plate adjacent to the electrostatic chuck such that the base substrate and a mask adhere closely to each other. The plate includes first magnet units in a first area of the plate and second magnet units in a second area of the plate that does not overlap the first area. The first magnet units are spaced apart from each other at a first distance, and the second magnet units are spaced apart from each other at a second distance that is greater than the first distance.

When the first voltage is applied to the first electrode area and the second voltage is applied to the second electrode area, at least a portion of the mask may contact the base substrate.

The method may further include aligning the base substrate and the mask.

When the mask is aligned with the base substrate, substantially the same voltage may be applied to the first electrode area and the second electrode area.

The same voltage may be lower than the first voltage.

A distance between one of the first magnet units and one of the second magnet units that is adjacent to the one of the first magnet units may be greater than the first distance.

The second magnet units may include first sub-magnet units spaced apart from each other at the second distance and second sub-magnet units spaced apart from each other at a third distance that is greater than the second distance. The first sub-magnet units may be closer to the first magnet units than the second sub-magnet units are.

A distance between one of the first magnet units and one of the second magnet units that is adjacent to the one of the first magnet units may be greater than the second distance.

A magnetic flux density of the first magnet units may be smaller than a magnetic flux density of the second magnet units.

When viewed on a plane, the first electrode area and the first area may overlap each other.

### BRIEF DESCRIPTION OF THE DRAWINGS

Embodiments will now be described more fully hereinafter with reference to the accompanying drawings; however, the present disclosure may be embodied in different forms and should not be construed as limited to the embodiments set forth herein. Rather, these embodiments are provided so that this disclosure will be thorough and complete and will fully convey the scope of the present disclosure to those skilled in the art.

FIG. 1 is a cross-sectional view schematically illustrating a deposition apparatus according to embodiments of the present disclosure.

FIG. 2 is a perspective view of a base substrate as a deposition target of the deposition apparatus shown in FIG. 1.

FIG. 3 is a perspective view of an electrostatic chuck and a plate shown in FIG. 1.

FIG. 4 is a cross-sectional view illustrating the plate shown in FIG. 1.

FIG. 5 is a flowchart describing steps of a method of operating the deposition apparatus shown in FIG. 1 according to an embodiment of the present disclosure.

FIGS. 6 to 8 are schematic cross-sectional views illustrating operation steps of the method of operating the deposition apparatus shown in FIG. 5.

FIG. 9 is a flowchart describing a method of operating the deposition apparatus shown in FIG. 1 according to another embodiment of the present disclosure.

### DETAILED DESCRIPTION

Hereinafter, embodiments of the present disclosure will be described in more detail with reference to the accompanying drawings. In the description below, aspects and features necessary to understand an operation according to embodiments of the present disclosure are described and the descriptions of other aspects and features may be omitted or shortened in order not to unnecessarily obscure the subject matter of the present disclosure. In addition, the present disclosure is not limited to the embodiments described herein and may be embodied in various different forms. Rather, the embodiments described herein are provided to thoroughly and completely describe the present disclosure to a person of ordinary skill in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

In addition, embodiments of the present disclosure are described here with reference to schematic diagrams of ideal embodiments (or of an intermediate structure) of the present disclosure such that changes in a shape as shown in the drawings due to, for example, manufacturing technology and/or tolerances may be expected. Therefore, the present disclosure shall not be limited to the specific shapes of a region shown herein but include shape deviations caused by, for example, the manufacturing technology. The regions shown in the drawings are schematic in nature, and the shapes thereof do not represent the actual shapes of the regions of the device, and do not limit the scope of the disclosure.

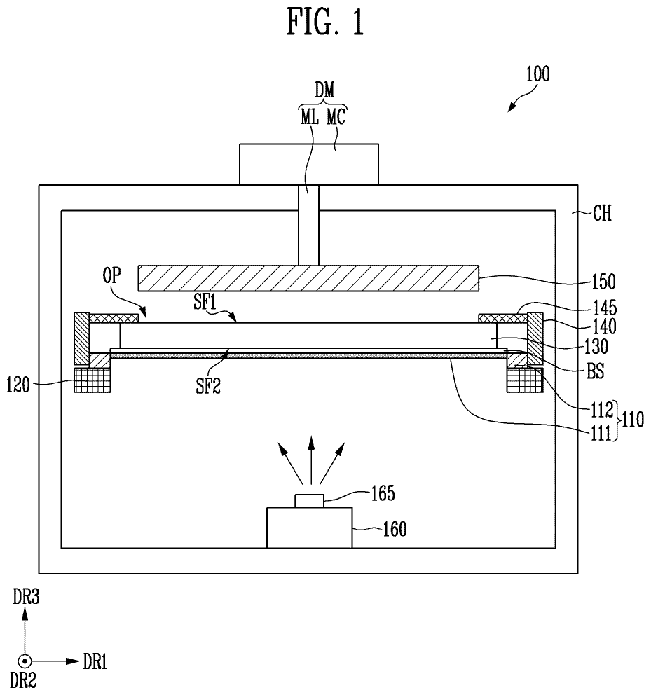

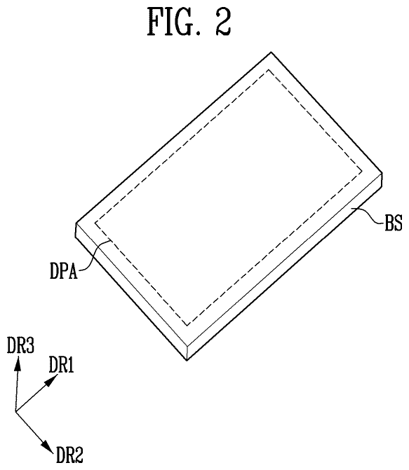

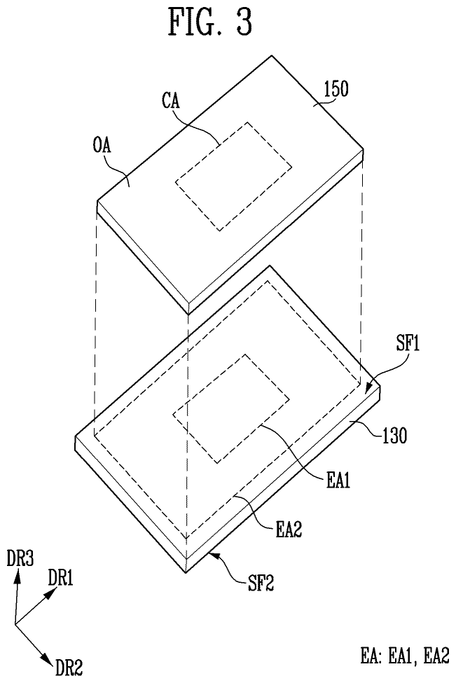

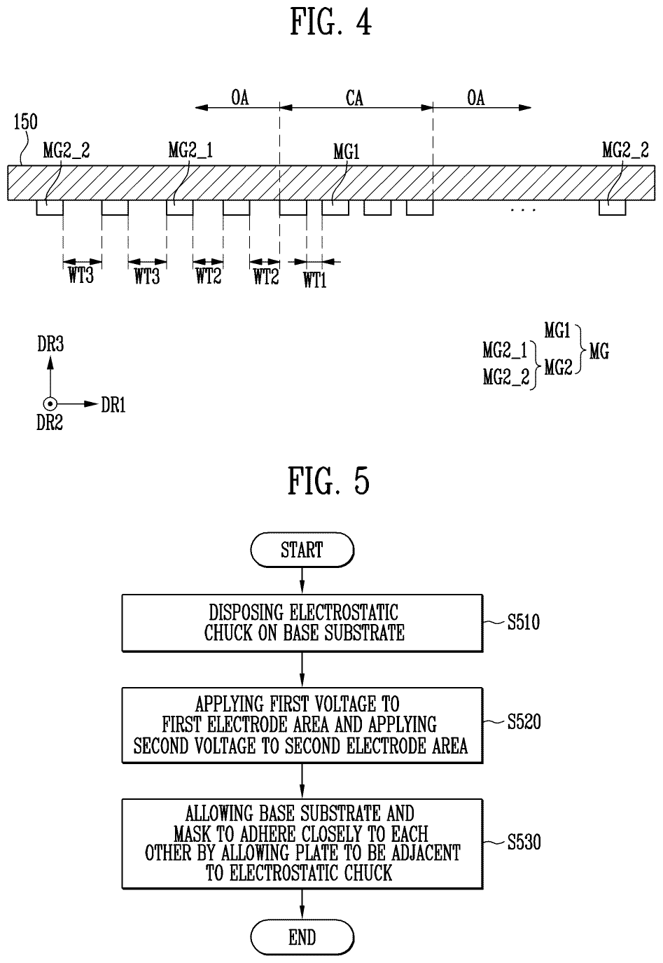

FIG. 1 is a cross-sectional view schematically illustrating a deposition apparatus according to embodiments of the present disclosure. FIG. 2 is a perspective view of a base substrate as a deposition target of the deposition apparatus shown in FIG. 1. FIG. 3 is a perspective view illustrating an electrostatic chuck and a plate shown in FIG. 1. FIG. 4 is a cross-sectional view of the plate shown in FIG. 1.

Referring to FIG. 1, a deposition apparatus 100, according to embodiments of the present disclosure, may deposit (or may be configured to deposit) a deposition material on a base substrate BS.

Further referring to FIG. 2, the base substrate BS may have a deposition area DPA, and the deposition material may be deposited on (or deposited to) the deposition area DPA. For convenience of description, FIG. 2 illustrates an embodiment in which the base substrate BS has one deposition area DPA. However, this is merely illustrative, and the base substrate BS may have a plurality of deposition areas DPA. In addition, the size and shape of the deposition area DPA of the base substrate BS shown in FIG. 2 are merely illustrative for convenience of description. The size and shape of the deposition area DPA may vary according to a deposition process.

The deposition area DPA of the base substrate BS may be parallel to a surface defined by a first directional axis (e.g., an axis extending in a first direction DR1) and a second directional axis (e.g., an axis extending in a second direction DR2). In addition, a normal direction of the deposition area DPA may be defined as a third direction DR3. The first to third directions DR1, DR2, and DR3 shown in the drawings are merely examples defined for convenience of description. The first to third directions DR1, DR2, and DR3 are relative concepts and may be changed to other directions. Hereinafter, for convenience of description, the first to third directions DR1, DR2, and DR3 are designated by like reference numerals.

Referring back to FIG. 1, the deposition apparatus 100 may include a chamber CH, a transfer unit DM, a mask assembly 110, a support member 120, an electrostatic chuck (ESC) 130, a driving unit (e.g., a driver) 140, a connection member 145, a plate 150, and a deposition source 160.

The chamber CH may have a space formed thereinside, and a deposition process may be performed in the space formed inside the chamber CH. For example, the mask assembly 110, the support member 120, the ESC 130, the driving unit 140, the connection member 145, the plate 150, the deposition source 160, and a transfer rod ML of the transfer unit DM may be disposed in the space formed inside the chamber CH.

In some embodiments, the chamber CH may be formed such that at least a portion thereof is open (or opened). For example, a gate valve or the like may be disposed in the open portion of the chamber CH, and the open portion of the chamber CH may be opened or closed by using the gate valve or the like.

The support member 120 may support and fix the mask assembly 110. Also, the support member 120 may move the mask assembly 110 up and/or down within a distance range (e.g., within a certain distance range) or rotate the mask assembly 110 within an angle range (e.g., within a certain angle range). Also, the support member 120 may linearly move the mask assembly 110 within a distance range (e.g., within a certain distance range) in various directions.

The mask assembly 110 may be disposed on the support member 120. The mask assembly 110 may include a mask 111 and a mask frame 112.

The mask frame 112 may have an opening through which the deposition material can pass and may include a plurality of frames surrounding (e.g., extending around a periphery of) the opening.

The mask frame 112 may support the mask 111. For example, the mask frame 112 may further include a support stick. The support stick may prevent a warpage phenomenon caused by the weight of the mask 111 itself and may support the mask frame 112.

The mask 111 may be disposed on the top of the mask frame 112. In some embodiments, one mask 111 may be disposed on the mask frame 112, or in other embodiments, a plurality of masks 111 may be disposed on the mask frame 112. For example, when a plurality of masks 111 are disposed on the mask frame 112, the plurality of masks 111 may be arranged in one direction (e.g., the first direction DR1 or the second direction DR2) to close (or cover) at least a portion of the opening defined in the mask frame 112. For convenience of description, hereinafter, an embodiment in which one mask 111 is provided to be disposed on the mask frame 112 and closes (or covers) at least a portion of the opening in the mask frame 112 will be primarily described.

The mask 111 may be a Fine Metal Mask (FMM) used to deposit (e.g., used to form) R, G, and B pixels on a substrate. The mask 111 may be formed of materials widely used for the FMM. For example, the mask 111 may be manufactured of stainless steel, Invar (also known as FeNi36), nickel (Ni), cobalt (Co), a nickel alloy, a nickel-cobalt alloy, and the like. The above-described materials have relatively low thermal expansion coefficients. Accordingly, a phenomenon in which the mask 111 is deformed by heat during a process of manufacturing the mask 111 can be mitigated or prevented.

The mask 111 may have at least one opening. When the opening is provided in plurality, the plurality of openings may be disposed such that a pattern is formed in at least a portion of the mask 111. Also, when the opening is provided in plurality, the plurality of openings may be disposed in a plurality of areas in the mask 111 to be distinguished from (or spaced apart from) each other and may be disposed such that a pattern is formed in each area.

The base substrate BS, on which the deposition material is to be deposited, may be disposed on (or arranged on) the mask assembly 110. The base substrate BS may be a mother substrate, which becomes a deposition target.

The deposition area DPA of the base substrate BS may be defined as an area corresponding to the at least one opening in the mask 111 of the mask assembly 110. Accordingly, an area on the base substrate BS exposed by (or exposed through) the at least one opening in the mask 111 may be defined as the deposition area DPA of the base substrate BS, and an area covered by the mask 111 may be defined as a non-deposition area of the base substrate BS.

The ESC 130 may be disposed on the base substrate BS. The ESC 130 may fix the base substrate BS, by using an electrostatic force, and cause the base substrate BS to adhere closely to the mask 111. The ESC 130 may be coupled to the base substrate BS to prevent the base substrate BS from moving in alignment (e.g., to prevent the base substrate BS from becoming misaligned) during the deposition process.

Referring to FIGS. 1 and 3, the ESC 130 may have a plurality of electrode areas EA. For example, the ESC 130 may have a first electrode area EA1 and a second electrode area EA2 not overlapping (e.g., offset from) the first electrode area EA1.

A plurality of electrodes may be included in the plurality of electrode areas EA. For example, at least one first electrode and at least one second electrode may be included in the first electrode area EA1. The at least one first electrode may have a first polarity, and the at least one second electrode may have a second polarity (e.g., a polarity opposite to the first polarity). For example, the first polarity may be a positive polarity (+), and the second polarity may be a negative polarity (−).

The driving unit 140 may drive the ESC 130. For example, the driving unit 140 may be connected to the ESC 130 by the connection member 145 to drive the ESC 130.

The driving unit 140 may include a power source, and the power source of the driving unit 140 may be supplied to the at least one first electrode and the at least one second electrode, which are included in the ESC 130, through the connection member 145. For example, the power source included in the driving unit 140 may include one terminal defined as a positive electrode and another terminal defined as a negative electrode. The one terminal of the power source may be connected to the first electrode such that a voltage having the positive polarity may be applied to the first electrode through the power source, and the other terminal of the power source may be connected to the second electrode such that a voltage having the negative polarity may be applied to the second electrode through the power source. Accordingly, the first electrode may have the positive polarity, and the second electrode may have the negative polarity.

When a voltage is applied to the ESC 130 through the power source of the driving unit 140, the ESC 130 may generate an electrostatic force. For example, when a voltage (e.g., a predetermined voltage) is applied to the first and second electrodes of the ESC 130 through the power source of the driving unit 140, the electrostatic force may be generated. Accordingly, the base substrate BS and the mask 111 may adhere closely to each other due to the electrostatic force. For example, the electrostatic force generated by the ESC 130 may attract the base substrate BS and the mask 111 in a direction toward the ESC 130. For example, gravitation (e.g., attraction or an attractive force) may be generated between the ESC 130 and the base substrate BS and/or between the ESC 130 and the mask 111, and the corresponding gravitation may attract the base substrate BS and the mask 111 in the third direction DR3. Accordingly, drooping of the base substrate BS and the mask 111 can be mitigated or prevented.

The first electrode area EA1 and the second electrode EA2 may be independently controlled. For example, the driving unit 140 may independently control a voltage applied to each of the first electrode area EA1 and the second electrode EA2. The driving unit 140 may independently apply a voltage to each of a plurality of first electrodes and a plurality of second electrodes, which are included in the first electrode area EA1 and the second electrode area EA2. Accordingly, electrostatic forces generated by the first electrode area EA1 and the second electrode area EA2 may be different from each other. For example, gravitation caused by first electrode area EA1 and gravitation caused by the second electrode area EA2, which are applied to the base substrate BS and the mask 111, may be different from each other.

The driving unit 140 may transfer (e.g., may move) the ESC 130 upwardly or downwardly. Also, the driving unit 140 may rotate the ESC 130 within an angle range (e.g., within a certain angle range) and may linearly move the ESC 130 within a distance range (e.g., a certain distance range) in various directions. For example, the driving unit 140 may include a device or a structure, such as a motor or a cylinder.

The connection member 145 may be in contact with at least a portion of an upper surface of the ESC 130 to connect the ESC 130 and the driving unit 140 to each other. For example, the connection member 145 may be in contact with a first surface SF1 of the ESC 130 to electrically connect the ESC 130 and the driving unit 140.

The connection member 145 may define (e.g., may have) an opening OP exposing at least a portion of the upper surface (e.g., the first surface SF1) of the ESC 130. The opening OP defined in the connection member 145 may be area in which the plate 150 is mounted. For example, the plate 150 may be mounted in the opening OP defined by the connection member 145 to allow the base substrate BS and the mask 111 to adhere closely to each other.

The plate 150 may be disposed to overlap with the ESC 130. The plate 150 may include a yoke plate including a permanent magnet. The plate 150 including the yoke plate is disposed to overlap with the ESC 130 so that the base substrate BS and the mask 111 can further adhere closely to each other by a magnetic field generated by the plate 150 in addition to the above-described electrostatic force generated by the ESC 130. For example, the magnetic field generated by the plate 150 attracts the mask 111 made of a metal in a direction (e.g., the third direction DR3) toward the plate 150 (e.g., gravitation or attraction is generated between the plate 150 and the mask 111) so that a coupling force between the base substrate BS and the mask 111 can be further increased and drooping of the base substrate BS and the mask 111 can be prevented.

The plate 150 may have a first area CA and a second area OA not overlapping with (e.g., offset from or spaced apart from) the first area CA. For example, the first area CA of the plate 150 may overlap with the first electrode area EA1, and the second area OA of the plate 150 may overlap with the second electrode area EA2.

The transfer unit DM may be connected to the plate 150. The transfer unit DM may include the transfer rod ML and a transfer body MC. The transfer body MC may transfer the plate 150 in the third direction DR3 and/or the opposite direction of the third direction DR3 by using the transfer rod ML. Also, through the transfer rod ML, the transfer body MC may rotate the plate 150 within an angle range (e.g., within a certain angle range) and may linearly move the plate 150 within a distance range (e.g., within a certain distance range) in various directions.

For example, the transfer body MC may be disposed outside of the chamber CH and may include any one of a cylinder and a motor. For example, when the transfer body MC includes the cylinder, the transfer rod ML may be a piston. In another embodiment, when the transfer body MC includes the motor, the transfer rod ML may be implemented as a ball screw shaft that can be moved up/down according to rotation (e.g., the rotation direction) of the motor. However, this is merely illustrative, and the transfer unit DM may include various devices capable of moving the plate 150.

The ESC 130 and the plate 150 may be driven and/or transferred independently from each other. For example, the ESC 130 may be driven and/or transferred by the driving unit 140, and the plate 150 may be driven and/or transferred by the transfer unit DM. As such, the ESC 130 and the plate 150 are driven and/or transferred independently from each other by different components such that alignment can be prevented from being distorted due to vibration. Accordingly, the yield of the deposition process can be improved.

The deposition source 160 may be disposed inside the chamber CH. The deposition material may be accommodated inside the deposition source 160.

The deposition source 160 may evaporate, toward the mask 111, at least one deposition material from among an organic material, an inorganic material, and a conductive material. The deposition material may be deposited on the deposition area DPA of the base substrate BS while passing through the at least one opening included in the mask 111. For example, the deposition source 160 may deposit the deposition material on (or to) the deposition area DPA of the base substrate BS by using a method of heating and evaporating the deposition material at high temperature. In an example, the deposition source 160 may include a heater for heating the deposition material.

The deposition apparatus 100 may further include a transfer means for moving the deposition source 160 in a horizontal direction (e.g., the first direction DR1 or the second direction DR2).

A nozzle unit 165 may be connected to the deposition source 160 to provide the evaporated or sublimated deposition material from the deposition source 160 to the outside. The nozzle unit 165 may include at least one nozzle. For example, the nozzle may be provided in the form of dot nozzles, which are disposed to be spaced apart from each other and are arranged in a dot form. In another embodiment, the nozzle may be provided in the form of a line nozzle, which sprays the deposition material onto a certain area.

Referring to FIG. 4, a plurality of magnet units MG may be disposed on the plate 150. For example, first magnet units MG1 may be disposed in the first area CA, and second magnet units MG2 may be disposed in the second area OA.

The plurality of magnet units MG may be disposed to be spaced apart from each other. For example, the magnet units MG may be spaced apart from each other in the first direction DR1 or the second direction DR2. In some embodiments, the magnetic units MG may be arranged in a matrix structure with respect to the first direction DR1 and the second direction DR2 on a plane. The first direction DR1 may be a row direction, and the second direction DR2 may be a column direction.

In some embodiments, the plurality of magnet units MG may alternately form (or have) different polarities. For example, a magnet unit forming an N pole and a magnet unit forming an S pole may be alternately disposed along the first direction DR1.

The plurality of magnet units MG may include a permanent magnet. For example, the magnet units MG may include a ferromagnetic body including a ferrite-based magnet, a neodymium-based magnet, a samarium cobalt-based magnet, or the like. However, the present disclosure is not limited thereto.

The first area CA of the plate 150 may correspond to a central area of the plate 150, and the second area OA may correspond to an outer area of the plate 150. For example, in a cross-sectional view, the plate 150 may have the first area CA adjacent to a virtual center line and the second area OA relatively more distant from the center line of the plate 150 than the first area CA is.

The first magnet units MG1 may be disposed to be spaced apart from each other at a certain distance. For example, the first magnet units MG1 may be disposed to be spaced apart from each other at a first distance WT1.

In some embodiments, any one of the first magnetic units MG1 and any one of the second magnet units MG2, which is adjacent to the corresponding first magnet unit MG1, may be disposed to be spaced apart from each other at a second distance WT2.

According to an embodiment of the present disclosure, a magnetic force applied to the ESC 130 and the mask 111 by the second area OA of the plate 150 may be stronger than a magnetic force applied to the ESC 130 and the mask 111 by the first area CA of the plate 150. For example, when a distance at which two adjacent magnets are disposed is smaller than a certain distance, a magnetic force which may be generated by the two magnets may become stronger as the distance between the two magnets becomes larger. For example, a magnetic force generated by second magnet units MG2 disposed to be spaced apart from each other at the second distance WT2 may be stronger than a magnetic force generated by first magnetic units MG1 disposed to be spaced apart from each other at the first distance WT1. Therefore, a magnetic force applied to the ESC 130 and the mask 111, which overlap with the second area OA, may be stronger than a magnetic force applied to the ESC 130 and the mask 111, which overlap with the first area CA. For example, the magnitude of a magnetic force applied in an upper direction (e.g., the third direction DR3) to the ESC 130 and the mask 111 by the plate 150 may be stronger (or may increase) nearer to both end portions from a central portion of each of the ESC 130 and the mask 111.

The second magnetic units MG2 may include first sub-magnet units MG2_1 and second sub-magnet units MG_2 disposed relatively more distant from the first magnet units MG1 than the firs sub-magnet units MG2_1 are. Each of the first sub-magnet units MG2_1 and the second sub-magnet units MG2_2 may be disposed to be spaced apart from each other at a constant distance. For example, the first sub-magnet units MG2_1 may be disposed to be spaced apart from each other at the second distance WT2, and the second sub-magnet units MG2_2 may be disposed to be spaced apart from each other at a third distance WT3, which is greater than the second distance WT2.

In some embodiments, any one of the first sub-magnet units MG2_1 and any one of the second sub-magnet units MG2_2, which is adjacent to the corresponding first sub-magnet unit MG2_1, may be disposed to be spaced apart from each other at the third distance WT3.

According to an embodiment of the present disclosure, a magnetic force generated by the second sub-magnet units MG2_2 spaced apart from each other by the third distance WT3, which is greater than the second distance WT2, may be stronger than a magnetic force generated by the first sub-magnet units MG2_1 spaced apart from each other by the second distance WT2. Therefore, the magnitude of the magnetic force applied in the upper direction to the ESC 130 and the mask 111 by the plate 150 may become stronger (e.g., may increase) nearer to (or approaching) both of the end portions from the central portion of each of the ESC 130 and the mask 111.

In some embodiments, a magnetic flux density of the first magnetic units MG1 may be smaller than a magnetic flux density of the second magnetic units MG2. For example, the magnetic flux density of the first magnetic units MG1 may be 400 Gauss or less, and the magnetic flux density of the second magnet units MG2 may be 450 Gauss or more. Accordingly, the magnetic force applied to the ESC 130 and the mask 111, which overlap with the first area CA, may be weaker than the magnetic force applied to the ESC 130 and the mask 111, which overlap with the second area OA, and the magnitude of the magnetic force applied in the upper direction to the ESC 130 and the mask 111 by the plate 150 may become weaker (or may decrease) nearer to (or approaching) the central portion from both of the end portions of each of the ESC 130 and the mask 111.

Next, a method of operating the deposition apparatus, according to an embodiment of the present disclosure, will be described with reference to FIGS. 5 to 8. In FIGS. 5 to 8, descriptions of portions already described above will be simplified or will not be repeated.

FIG. 5 is a flowchart describing steps of a method of operating the deposition apparatus according to an embodiment of the present disclosure.

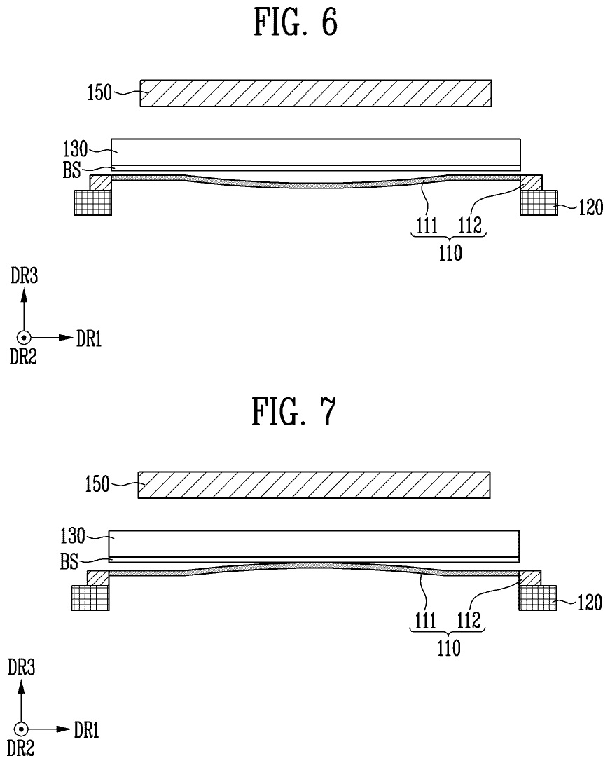

FIGS. 6 to 8 are schematic cross-sectional views illustrating operation steps of the method of operating the deposition apparatus described in FIG. 5.

Referring to FIG. 5, the method of operating the deposition apparatus 100, according to an embodiment of the present disclosure, may include step S510 of disposing an electrostatic chuck (ESC) on a base substrate, step S520 of applying a first voltage to a first electrode area and applying a second voltage to a second electrode area, and step S530 of allowing the base substrate and a mask to adhere closely to each other by allowing a plate to be adjacent to the ESC.

Referring to FIGS. 5 and 6, in step S510, the ESC 130 having the first electrode area EA1 and the second electrode area EA2 different from the first electrode area EA1 may be disposed on the base substrate BS.

In this step, the base substrate BS may adhere closely to the ESC 130. For example, referring to FIGS. 1 and 3 together, a voltage may be applied to the ESC 130 through the power source of the driving unit 140. For example, a voltage may be applied to a plurality of electrodes included in the first electrode area EA1 and the second electrode area EA2. Accordingly, gravitation (or attraction) may be generated in a direction (e.g., the third direction DR3) from the base substrate BS toward the ESC 130, and the base substrate BS may adhere closely to the ESC 130.

In this step, the direction of a net force applied to the mask 111 may be a lower direction (e.g., the opposite direction of the third direction DR3), and accordingly, the mask 111 may be warped (or may sag) in the lower direction. For example, attraction applied in an upper direction (e.g., the third direction DR3) to the mask 111 by the ESC 130 may not be strong in the mask 111 relatively distant from the ESC 130. In addition, because the support member 120 and the mask frame 112 support only both sides (e.g., one side and the other side facing the one side) of the mask 111, a supporting force for supporting the mask 111 may become weaker more distant from the sides of the mask 111. For example, gravity having a substantially same magnitude acts throughout the entire area of the mask 111, but the magnitude of a supporting force in the upper direction, caused by the support member 120 and the mask frame 112, may decrease farther from the support member 120 and the mask frame 112. Accordingly, a net force in the lower direction, which acts on the mask 111, may become stronger nearer to a central portion of the mask 111, and a drooping (or sagging) phenomenon of the central portion of the mask 111 may occur. In addition, as a display device as a deposition target of the deposition apparatus 100 becomes large-sized, the size of each of the base substrate BS and the mask 111 are increased, and therefore, a warpage phenomenon of the mask 111 may become more serious.

Referring to FIGS. 5 and 7, in step S520, a first voltage may be applied to the first electrode area EA1, and a second voltage may be applied to the second electrode area EA2. Accordingly, a magnitude of an electrostatic force formed in the first electrode area EA1 and a magnitude of an electrostatic force formed in the second electrode area EA2 may be different from each other. For example, gravitation (or attraction) applied to the base substrate BS and the mask 111 at the first electrode area EA1 may be stronger than gravitation applied to the base substrate BS and the mask 111 at the second electrode area EA2.

Gravitation applied to the mask 111 overlapping the first electrode area EA1 may be stronger than gravitation applied to the mask 111 overlapping the second electrode area EA2. Accordingly, the central portion of the mask 111 may be more strongly drawn (or pulled) in the upper direction (e.g., in the third direction DR3), and thus, a warpage phenomenon of the central portion of the mask 111 in the lower direction can be reduced or prevented. For example, because the central portion of the mask 111 is warped in the upper direction, at least a portion of the mask 111 may be in contact with the base substrate BS.

Referring to FIGS. 5 and 8, in step S530, the base substrate BS and the mask 111 may adhere closely to each other by allowing the plate 150 to be adjacent to the ESC 130.

In this step, the plate 150 may move in the lower direction (e.g., in the direction opposite to the third direction DR3). Accordingly, the base substrate BS and the mask 111 may be drawn in the upper direction by a magnetic force of the plate 150, and the base substrate BS and the mask 111 may adhere closely to each other.

Referring to FIGS. 5 and 8, together with FIG. 4, a magnetic force applied to the ESC 130 and the mask 111 by the first magnetic units MG1 may be weaker than a magnetic force applied to the ESC 130 and the mask 111 by the second magnetic units MG2. Accordingly, a magnetic force applied to the ESC 130 and the mask 111, which correspond to the first area CA, may be weaker than a magnetic force applied to the ESC 130 and the mask 111, which correspond to the second area OA.

When a substrate, as a target to be deposited, and a portion of a mask are not in contact with each other (e.g., are spaced apart from each other), a distance between a central portion of the mask and the substrate may be relatively large due to a warpage phenomenon of the central portion of the mask. To allow the substrate and the mask to adhere closely to each other, a magnetic force generated at a central portion of a plate should be strong, and the substrate and the mask, which are attracted by a strong magnetic field may collide with each other in a corresponding process. Accordingly, there exists a risk that the substrate and the mask will be damaged.

On the other hand, according to embodiments of the present disclosure, at least a portion of the central portion of the mask 111 may be in a state in which the at least portion is in contact with the base substrate BS before the plate 150 moves in the lower direction. Accordingly, even when the magnetic field applied to the mask 111 and the base substrate BS by the plate 150 is relatively weak, the mask 111 and the base substrate BS can stably adhere closely to each other. For example, when the mask 111 and the base substrate BS adhere closely to each other, an impact between the mask 111 and the base substrate BS may not be large (e.g., may be limited in energy or size). Accordingly, a risk that the mask 111 and the base substrate BS will be damaged can be minimized or at least reduced, and the reliability of a deposition process of the deposition apparatus 100 can be improved.

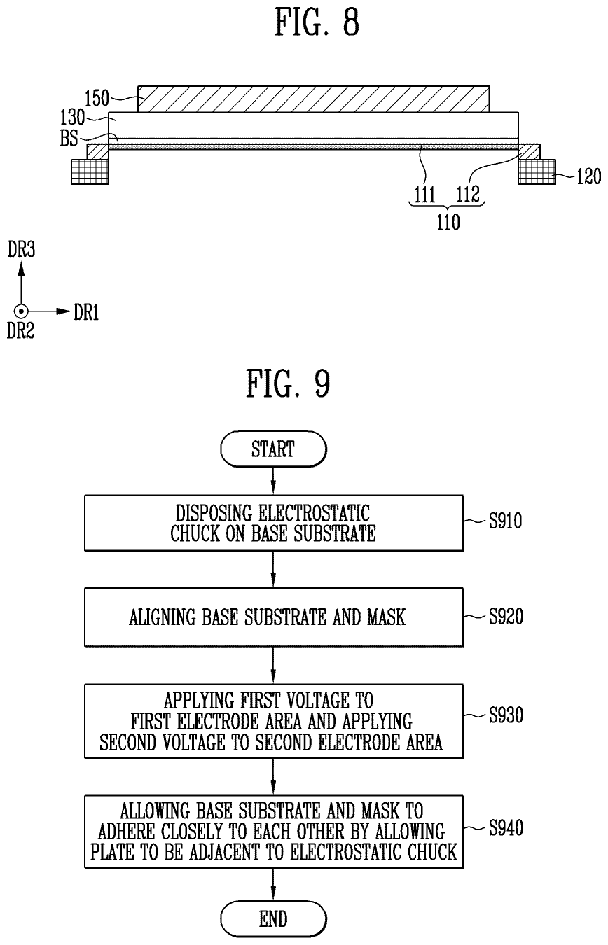

FIG. 9 is a flowchart describing steps of a method of operating the deposition apparatus according to another embodiment of the present disclosure.

Referring to FIG. 9, a method of operating the deposition apparatus 100, according to another embodiment of the present disclosure, may include step S910 of disposing an electrostatic chuck (ESC) on a base substrate, step S920 of aligning the base substrate and a mask, step S930 of applying a first voltage to a first electrode area and applying a second voltage to a second electrode area, and step S940 of allowing the base substrate and the mask to adhere closely to each other by allowing a plate to be adjacent to the ESC.

Steps S910, S930, and S940 may be similar to steps S510, S520, and S530, described in connection with FIG. 5, and overlapping descriptions will be omitted.

Referring to FIGS. 6 and 9, the base substrate BS and the mask 111 may be aligned. For example, the mask may be aligned with respect to the base substrate BS such that any one of the openings in the mask 111 accurately corresponds to a portion (e.g., a pixel) on the base substrate BS.

In this step, the ESC 130 may be in a state in which the ESC 130 is disposed on the base substrate BS, and a substantially same voltage may be applied to the first electrode area EA1 and the second electrode area EA2 of the ESC 130. Accordingly, the base substrate BS can stably maintain the state in which the base substrate BS is in contact with the ESC 130 by an electrostatic force in the upper direction, which is generated by the ESC 130.

Referring to FIGS. 6 and 9, together with FIG. 7, in this step, a voltage lower than the first voltage may be applied to the first electrode area EA1 and the second electrode area EA2 of the ESC 130. Accordingly, the mask 111 can be less influenced by an electrostatic force generated by the ESC 130, and the alignment between the mask 111 and the base substrate BS can be smoothly made. For example, when a relatively low voltage is applied to the ESC 130, the electrostatic force generated by the ESC 130 is relatively weak, and therefore, gravitation (or attraction) in the upper direction, which is applied to the mask 111, may also be relatively weak. Accordingly, movement of the mask 111 in the horizontal direction (e.g., the first direction DR1) is not limited, and the mask 111 and the base substrate BS can be easily aligned.

In the deposition apparatus and the method of operating the same according to embodiments of the present disclosure, the deposition apparatus includes an electrostatic chuck including electrode areas controlled independently from each other and magnet units disposed to be spaced apart from each other at a certain distance so that the reliability of the deposition apparatus can be improved.

Embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with one embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

What is claimed is:

1. A deposition apparatus comprising:
a base substrate;
an electrostatic chuck on the base substrate; and
a plate on the electrostatic chuck, the plate having a first area in which first magnet units are arranged and a second area in which second magnet units are arranged,
wherein the first magnet units are spaced apart from each other at a first distance, and the second magnet units are spaced apart from each other at a second distance, the second distance being greater than the first distance.

2. The deposition apparatus of claim 1, wherein a distance between one of the first magnet units and one of the second magnet units adjacent to the one of the first magnet units is greater than the first distance.

3. The deposition apparatus of claim 1, wherein the second magnet units comprise first sub-magnet units spaced apart from each other at the second distance and second sub-magnet units spaced apart from each other at a third distance, the third distance being greater than the second distance, and
wherein the first sub-magnet units are closer to the first magnet units than the second sub-magnet units are.

4. The deposition apparatus of claim 3, wherein a distance between one of the first magnet units and one of the second magnet units adjacent to the one of the first magnet units is greater than the second distance.

5. The deposition apparatus of claim 1, wherein a magnetic flux density of the first magnet units is smaller than a magnetic flux density of the second magnet units.

6. The deposition apparatus of claim 1, wherein the electrostatic chuck has a first electrode area and a second electrode area different from the first electrode area, and
wherein, when viewed on a plane, the first electrode area and the first area overlap with each other.

7. The deposition apparatus of claim 6, further comprising a driver configured to independently control a voltage applied to each of the first electrode area and the second electrode area.

8. The deposition apparatus of claim 1, wherein at least one of the first magnet units and the second magnet units comprises a permanent magnet.

9. A deposition apparatus comprising:
a base substrate;
an electrostatic chuck on the base substrate, the electrostatic chuck having a first electrode area and a second electrode area different from the first electrode area;
a driver configured to independently control a voltage applied to each of the first electrode area and the second electrode area; and
a plate on the electrostatic chuck, the plate having a first area in which first magnet units are arranged and a second area in which second magnet units are arranged.

10. A method of operating a deposition apparatus, the method comprising:
arranging, on a base substrate, an electrostatic chuck having a first electrode area and a second electrode area different from the first electrode area;
applying a first voltage to the first electrode area and applying a second voltage that is lower than the first voltage to the second electrode area; and
arranging a plate to be adjacent to the electrostatic chuck such that the base substrate and a mask to adhere closely to each other,
wherein the plate comprises first magnet units arranged in a first area of the plate and second magnet units arranged in a second area of the plate that does not overlap with the first area, and
wherein the first magnet units are spaced apart from each other at a first distance, and the second magnet units are spaced apart from each other at a second distance, the second distance being greater than the first distance.

11. The method of claim 10, wherein, when the first voltage is applied to the first electrode area and the second voltage is applied to the second electrode area, at least a portion of the mask contacts the base substrate.

12. The method of claim 10, further comprising aligning the base substrate and the mask.

13. The method of claim 12, wherein, when the mask and the base substrate are aligned, substantially the same voltage is applied to the first electrode area and the second electrode area.

14. The method of claim 13, wherein the same voltage is lower than the first voltage.

15. The method of claim 10, wherein a distance between one of the first magnet units and one of the second magnet units that is adjacent to the one of the first magnet units is greater than the first distance.

16. The method of claim 10, wherein the second magnet units comprise first sub-magnet units spaced apart from each other at the second distance and second sub-magnet units spaced apart from each other at a third distance, the third distance being greater than the second distance, and
wherein the first sub-magnet units are closer to the first magnet units than the second sub-magnet units are.

17. The method of claim 16, wherein a distance between one of the first magnet units and one of the second magnet units that is adjacent to the one of the first magnet units is greater than the second distance.

18. The method of claim 10, wherein a magnetic flux density of the first magnet units is smaller than a magnetic flux density of the second magnet units.

19. The method of claim 10, wherein, when viewed on a plane, the first electrode area and the first area overlap each other.
